(19) United States
(12) Patent Application Publication
(10) Pub. No.: US 2007/0152279 A1
(43) Pub. Date: Jul. 5, 2007

(54) SRAM DEVICE

(76) Inventor: Dae Kyeun Kim, Gyoonggi-do (KR)

Correspondence Address: SHERR & NOURSE, PLLC, 620 HERNDON PARKWAY, SUITE 200, HERNDON, VA, 20170, US

(21) Appl. No.: 11/617,224

(22) Filed: Dec. 28, 2006

(30) Foreign Application Priority Data
Dec. 30, 2005 (KR) 10-2005-0134771
Dec. 30, 2005 (KR) 10-2005-0134788

(51) Int. Cl. H01L 29/76

(52) U.S. Cl. 257/371; 257/E27.067

(57) ABSTRACT

In a disclosed SRAM device, a contact connected to a source of an NMOS transistor is formed along a straight portion of an active region, rather than in a bent part. An NMOS source contact may be positioned along the same line as that of a corresponding PMOS drain contact, and may be positioned symmetrically to an NMOS drain contact based on a corresponding gate. NMOS source contacts may be asymmetrically arranged. An active region has a curved portion having a rounded corner. A process margin for forming contacts over the active region may be increased, and electric characteristics such as leakage current or standby current may be improved, thereby causing the yield of an SRAM device to be enhanced.

The present application claims priority under 35 U.S.C. 119 and 35 U.S.C. 365 to Korean Patent Application No. 10-2005-0134771 (filed on Dec. 30, 2005), and to Korean Patent Application No. 10-2005-0134788 (filed on Dec. 30, 2005), which are hereby incorporated by reference in their entirety.

### BACKGROUND

As is generally known, an SRAM device is a kind of semiconductor memory device. Unlike DRAM devices, because the SRAM device maintains stored information while a power is supplied thereto, a periodical refresh is not required. Although fewer SRAM devices can be integrated on a given area in comparison the DRAM, SRAM has low power consumption and high response speed. Generally, an SRAM device cell includes six transistors, including, two pull-down transistors, two pull-up transistors, and two access transistors.

FIG. 1 is a schematic layout view showing a cell of an SRAM device according to the related art. FIG. 2 is a cross-sectional view of the cell of the SRAM device taken along line A-A of FIG. 1.

With reference to FIGS. 1 and 2, in order to form a pull-down NMOS transistor 10a and a pull-down PMOS transistor 10b, an N-well 11 and a P-well 11b are formed over a silicon substrate. An active region 13 is defined by a device isolation layer 12 formed on the silicon substrate. A gate 14 is formed over the silicon substrate to intersect the active region 13. Source/drain 15a/15b are formed in the active region on both sides of the gate 14, respectively. The source/drain 15a/15b and the gate 14 are connected to a lower metal wiring 17 through contacts 16a, 16b, and 16c. Silicide layers 18 are formed over lower portions of the source/drain 15a/15b and the gate 14, respectively.

In the SRAM cell having the construction described above, a contact region 16b in the drain 15b of the PMOS transistor and a contact region 16a of the NMOS transistor are weak regions, which may generate a leakage current during read/memory operations of the SRAM. However, in the SRAM device according to the related art, a process margin shortage, or a lack of a margin of error for the process, is inevitably caused by the layout. That is, as shown in FIG. 1, in the case of the PMOS transistor 10b, contacts 16b are positioned at both ends of the active region 13, whereas in the case of the NMOS transistor 10a, contacts 16a are positioned at a bend in the active region 13. Accordingly, margins for the active region and contact registration process are inevitably lacking. In particular, in the case of the NMOS transistor 10a in which the contact 16a is positioned at a bend in the active region 13, when the contact is wrongly arranged or the size of the contact is increased slightly, it can exert a bad influence on the leakage current characteristics of the SRAM device.

Moreover, when the contact 16a is positioned at the bend in the active region 13, the active region 13 has a sharp shape in order to secure a contact space to the utmost. However, such a shape is a weak structure vulnerable to stress, thereby allowing a dislocation of the active region 13. To solve the problems, an additional annealing process is required.

Moreover, as shown in FIG. 2, although the contact 16b of the PMOS drain 15b and the contact 16a of the NMOS source 15a are bounded with each other through a metal wiring 17, they are isolated from each other using a wide device isolation layer 12, which reduces the margins available in the metal wiring process. This also may exert a bad influence upon leakage current characteristics due to the contact arrangement and size.

### SUMMARY

Embodiments relate to a manufacturing technology of a semiconductor device, more particularly to a static random access memory (referred to as ‘SRAM’ hereinafter) device, which may increase process margins for forming contacts and improve leakage current characteristics by changing a cell layout to move the position of a source contact in an NMOS transistor.

Accordingly, embodiments relate to an SRAM device that substantially obviates one or more problems due to limitations and disadvantages of the related art.

Embodiments relate to an SRAM device, which can increase process margins for forming contacts, improve electric characteristics such as leakage current or standby current, and enhance the yield of the SRAM device by changing a cell layout of an SRAM.

Embodiments relate to an SRAM device, which reduces stress points by improving a curved shape of an active region, prevents a dislocation of an active region, simplifies a process and reduces costs by omitting an annealing process.

Additional advantages, objects, and features of the embodiments will be set forth in part in the description which follows and in part will become apparent to those having ordinary skill in the art upon examination of the following or may be learned from practical experience with the embodiments. The objectives and other advantages of the embodiments may be realized and attained by the structure particularly pointed out in the written description and claims hereof as well as the appended drawings.

Embodiments relate to an SRAM device including an NMOS transistor and a PMOS transistor, including an N-well and a P-well formed over a silicon substrate. A device isolation layer defines an active region formed on the silicon substrate. A gate is formed over the active region. Source/drain areas are formed in the active region on both sides of the gate. Contacts are connected to the source/drain areas and the gate. A contact connected to a source of the NMOS transistor is formed in a straight portion of the active region.

The source contact of the NMOS transistor may be disposed symmetrically with a drain contact of the NMOS transistor with respect to the gate. The source contact of the NMOS transistor may be asymmetrically arranged with respect to a drain contact of the PMOS transistor and the gate. The active region has a bend having a rounded corner.

Embodiments relate to an SRAM device including an NMOS transistor and a PMOS transistor including an N-well and a P-well formed over a silicon substrate. A device isolation layer defines an active region formed on the silicon substrate. A gate is formed over the active region. Source/drain areas are formed in the active region on both sides of the gate. Contacts are connected to the source/drain areas and the gate. A first portion of the active region and a second portion of the active region extend to be adjacent to each other, a contact connected to a source of the NMOS transistor is formed at the first active region, and a contact connected to a drain of the PMOS transistor is formed at the second active region, so that a device isolation layer between the first and second active regions has a narrower width that of a device isolation layer between other active regions. The N-well and the P-well may be spaced apart from each other by a predetermined distance. The source contact of the NMOS transistor is asymmetrically arranged with respect to the isolation layer and the PMOS transistor.

It is to be understood that both the foregoing general description and the following detailed description of the embodiments are exemplary and explanatory and are intended to provide further explanation of the claims.

### BRIEF DESCRIPTION OF THE DRAWINGS

FIG. 1 is a schematic layout view showing a cell of an SRAM device according to the related art;

FIG. 2 is a cross-sectional view of the cell of the SRAM device taken along line A-A of FIG. 1;

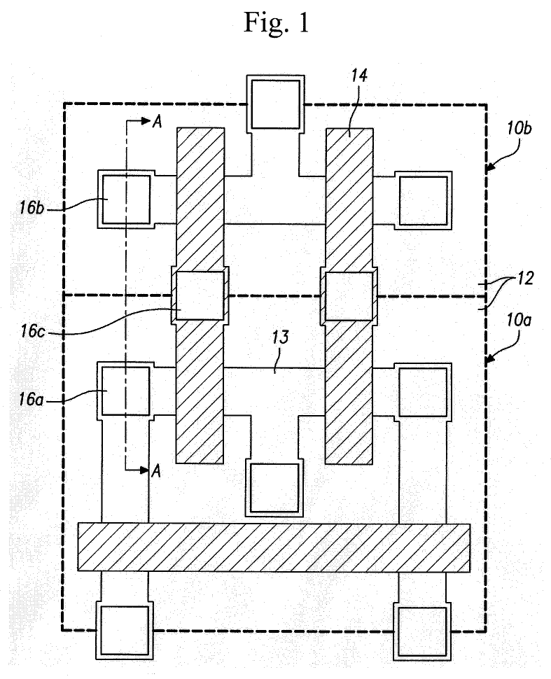

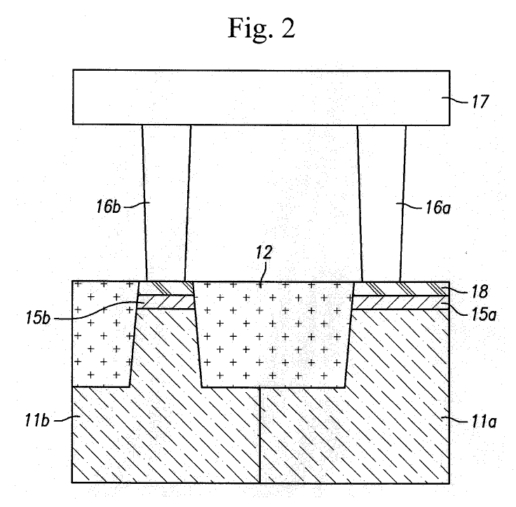

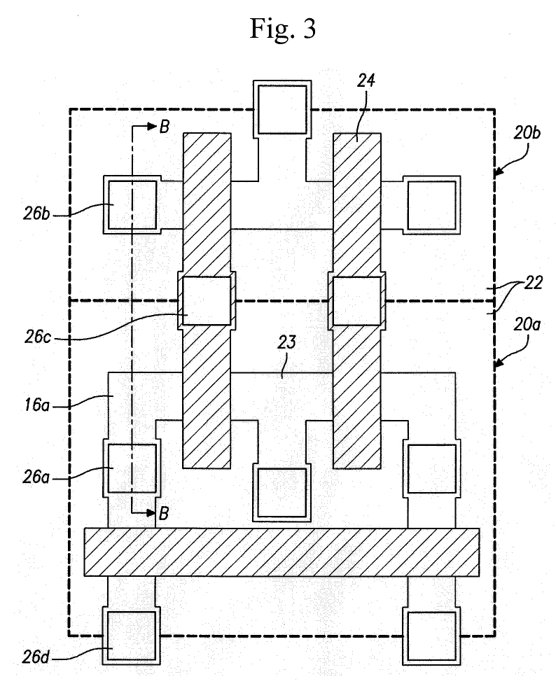

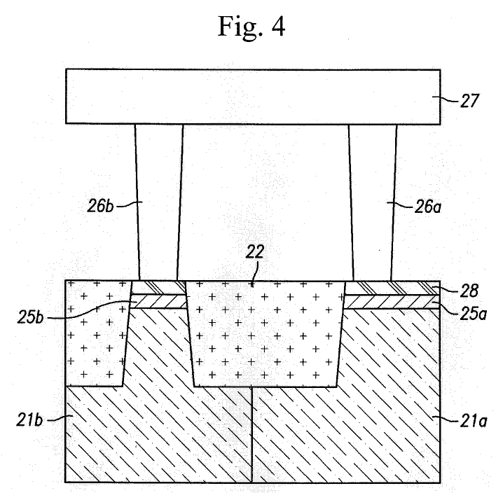

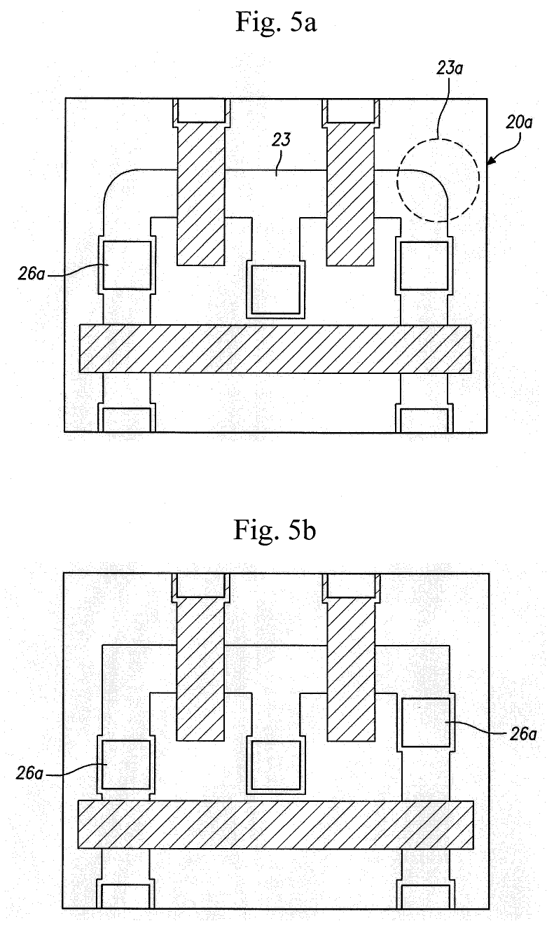

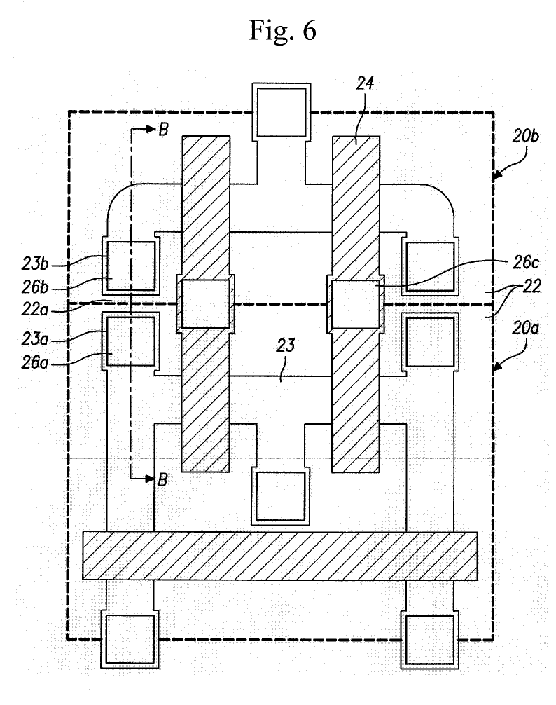

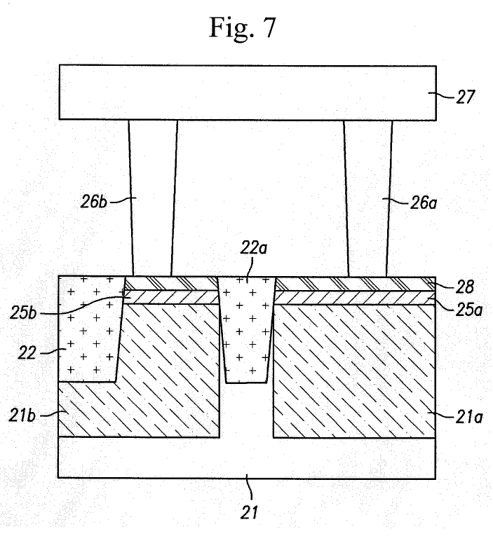

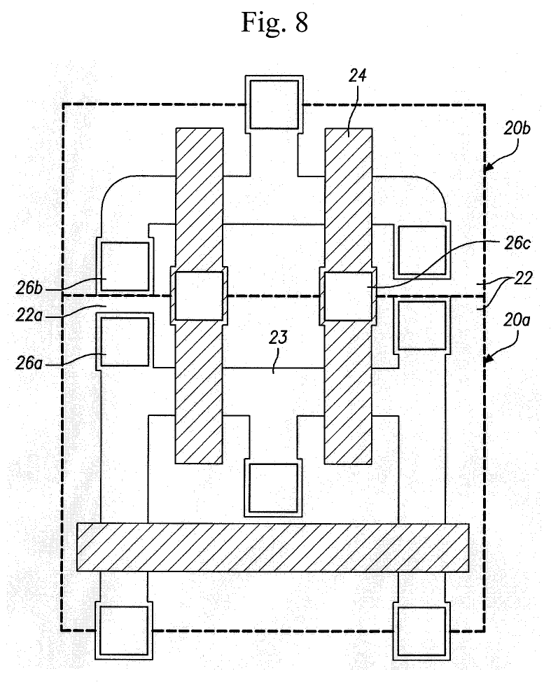

Example FIG. 3 is a schematic layout view showing a cell of an SRAM device according to embodiments;

Example FIG. 4 is a cross-sectional view of the cell of the SRAM device taken along line B-B of FIG. 3;

Example FIGS. 5A and 5B are schematic layout views showing a cell of an SRAM device according to embodiments;

Example FIG. 6 is a schematic layout view showing a cell of an SRAM device according embodiments;

Example FIG. 7 is a cross-sectional view of the cell of the SRAM device taken along line B-B of FIG. 6; and

Example FIG. 8 is a schematic layout view showing a cell of an SRAM device according to embodiments.

### DETAILED DESCRIPTION

With reference to FIGS. 3 and 4, to form a pull-down NMOS transistor 20a and a pull-up PMOS transistor 20b of the SRAM device, and an N-well 21a and a P-well 21b are formed over a silicon substrate. A device isolation layer 22 is formed on a silicon substrate using a shallow trench isolation (STI) method. An active region 23 is determined by the device isolation layer 22, and a gate 24 is formed over the silicon substrate to intersect the active region 23. Source/drain 25a/25b are formed in the active region 23 at both sides of the gate 24, respectively. The source/drain 25a/25b and the gate 24 are connected to a lower metal wiring 27 through contacts 26a, 26b, 26c, and 26d. Silicide layers 28 are formed over upper surfaces of the source/drain 25a/25b and the gate 24, respectively.

In particular, in the related art, a source contact 26a of the NMOS transistor 20a is positioned over a bend in the active region 23. However, in embodiments, the source contact 26a of the NMOS transistor 20a is positioned away from the bend on a straight portion of the active region 23.

The reason for changing the position of the NMOS source contact 26a from the plane of the PMOS drain contact 26b to a straight portion of the active region 23 is to maintain a minimum design rule related to an ion implantation and an active region. The position of the NMOS source contact 26a can be determined by considerations of the margins of an active region and a contact registration process. A maximum allowable deviation in position is a position symmetrical to the NMOS drain contact 26d based on the corresponding gate 14.

FIGS. 5A and 5B are schematic layout views showing a cell of an SRAM device according to embodiments.

With reference to FIG. 5A, when an NMOS source contact 26a is arranged on straight portion of the active region 23, it is not necessary to form the bend 23a of the active region 23 to have a sharp corner. Accordingly, the bend 23a of the active region 23 is formed to have a rounded corner to reduce stress points and prevent a dislocation of the active region 23. Further, by omitting a subsequent annealing process, the process according to embodiments may be simplified and a cost may be reduced.

Furthermore, as shown in FIG. 5B, to allow for additional process margins, the position of the NMOS source contact 26 may be asymmetrically arranged. Such a construction can cause the process margin in forming contacts to be further increased in an SRAM design, which contains many copies of a unit cell.

In the SRAM device according to embodiments shown in FIGS. 3-4, a source contact of an NMOS transistor is arranged on a straight portion of an active region instead of a bent portion thereof, which allows a greater process margin of the active region and a contact, and electric characteristics such as leakage current or standby current to be improved. This causes the yield of an SRAM device to be enhanced.

Further, when an NMOS source contact is arranged on a straight portion of the active region, it is not necessary to form a bend in the active region with a sharp corner. Accordingly, the bend in the active region is formed with a rounded shape to reduce stress points and prevent a dislocation of the active region. Moreover, it can simplify a process and reduce costs by omitting an annealing process.

A position of an NMOS source contact may be asymmetrically arranged to further secure a contact process margin.

FIG. 6 is a schematic layout view showing a cell of an SRAM device according embodiments and FIG. 7 is a cross-sectional view of the cell of the SRAM device taken along line B-B of FIG. 6.

With reference to FIGS. 6 and 7, to form a pull-down NMOS transistor 20a and a pull-up PMOS transistor 20b of the SRAM device, an N-well 21a and a P-well 21b are formed over a silicon substrate. A device isolation layer 22 is formed on a silicon substrate using a shallow trench isolation (STI) method. An active region 23 is determined by the device isolation layer 22, and a gate 24 is formed over the silicon substrate to intersect the active region 23. Source/drain 25a/25b are formed in the active region 23 at both sides of the gate 24, respectively. The source/drain 25a/25b and the gate 24 are connected to a lower metal wiring 27 through contacts 26a, 26b, 26c, and 26d. Silicide layers 28 are formed over upper surfaces of the source/drain 25a/25b and the gate 24, respectively.

In particular, in the SRAM device according to the related art, the contact 16b of the PMOS drain 15b and the contact 16a of the NMOS source 15a are connected to each other. In consideration of this, in the SRAM device according to embodiments, a first region 23 and a second region 23b extend using a relatively narrow device isolation layer 22a instead of a wide device isolation layer. An NMOS source contact 26a is positioned at the first active region 23a, and a PMOS drain contact 26b is positioned at the second active region 23b. The first active region 23a and the second active region 23b therefore extend to be adjacent to each other. A device isolation layer 22a between the first and second active regions 23a and 23b has a relatively narrower width that of a device isolation layer 22 between other active regions 23.

Accordingly, contacts according to the related art positioned at both ends and a curved part of the active region 23 can be moved to active regions 23a and 23b of a wide part. According to embodiments, a process margin can be secured in an active region and contacts, and thereby create an SRAM cell with improved electric characteristics such as leakage current or standby current, that results in an improvement in the yield of the SRAM device. On the other hand, the width of the shallow device isolation layer 22a satisfies a minimum design rule.

By using the shallow device isolation layer 22a, the N-well 21a and the P-well 21b are spaced apart from each other by a predetermined distance using a well isolation. This is to prevent a short-circuit between the N-well 21a of the NMOS transistor and the N-type drain 24b of the PMOS transistor, and between the P-well 21b of the PMOS transistor and a P-type source 25a of the NMOS transistor. A distance between the wells 21a and 21b can be set corresponding to the width of a wide device isolation layer according to the related art. However, if necessary, it can be set conforming to the characteristics of a device.

By extending an active region 23b in which a PMOS drain contact 26b is positioned and changing a contact formation position from both ends of the active region to the extended part 23b, it is not necessary to form an active region 23 with a sharp corner. Accordingly, a bend in the active region 23 is formed to have a rounded shape to reduce stress points and prevent a dislocation of the active region 23. Moreover, the embodiments may simplify the process and reduce costs by omitting an annealing process.

FIG. 8 is a schematic layout view showing a cell of an SRAM device according to further embodiments.

As shown in FIG. 8, a pair of left and right NMOS source contacts 26a may be asymmetrically arranged. In the same manner, a pair of left and right PMOS source contacts 26b may be asymmetrically arranged. This construction can help increase process margins for forming contacts in an SRAM design, which builds memory capacity by repeating a unit cell.

In the SRAM device according to embodiments, in place of a wide device isolation layer according to the related art, active regions in which an NMOS source contact and a PMOS drain contact are positioned are formed by creating a shallow device isolation layer. Accordingly, the position of contacts can be moved to an active region of a wide part and a sharp corner of the active region can be improved. In addition, a pair of left and right contacts may be asymmetrically arranged.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An SRAM device including an NMOS transistor and a PMOS transistor, comprising:
an N-well and a P-well formed over a silicon substrate;
a device isolation layer which defines an active region formed on the silicon substrate;
a gate formed over the active region;
source/drain areas formed in the active region on both sides of the gate; and
contacts connected to the source/drain areas and the gate,
wherein a contact connected to a source of the NMOS transistor is formed in a straight portion of the active region.

2. The SRAM device according to claim 1, wherein the source contact of the NMOS transistor is disposed symmetrically with a drain contact of the NMOS transistor with respect to the gate.

3. The SRAM device according to claim 1, wherein the source contact of the NMOS transistor is asymmetrically arranged with respect to a drain contact of the PMOS transistor and the gate.

4. The SRAM device according to claim 1, wherein the active region has a bend having a rounded corner.

6. An SRAM device including an NMOS transistor and a PMOS transistor, comprising:
an N-well and a P-well formed over a silicon substrate;
a device isolation layer defining an active region formed on the silicon substrate;
a gate formed over the active region;
source/drain areas formed in the active region on both sides of the gate; and
contacts connected to the source/drain areas and the gate,
wherein a first portion of the active region and a second portion of the active region extend to be adjacent to each other, a contact connected to a source of the NMOS transistor is formed at the first active region, and a contact connected to a drain of the PMOS transistor is formed at the second active region, and a device isolation layer between the first and second active regions has a narrower width that of a device isolation layer between other active regions.

7. The SRAM device according to claim 6, wherein the N-well and the P-well are spaced apart from each other by a predetermined distance.

8. The SRAM device according to claim 6, wherein the active region has a bend having a rounded corner.

9. The SRAM device according to claim 6, wherein the source contact of the NMOS transistor is asymmetrically arranged with respect to the isolation layer and the PMOS transistor.

10. The SRAM device according to claim 6, wherein the source contact of the PMOS transistor is asymmetrically arranged with respect to the isolation layer and the NMOS transistor.
